(19) United States
(12) Patent Application Publication
(10) Pub. No.: US 2026/0118414 A1
(43) Pub. Date: Apr. 30, 2026

(54) SINGLE WAFER-LEVEL CIRCUIT TESTING SYSTEM AND TESTING METHOD THEREOF

(71) Applicant: CHUNGHWA PRECISION TEST TECH. CO., LTD., TAOYUAN CITY (TW)

(72) Inventors: Kun chieh HSU, TAOYUAN CITY (TW); Yang-zheng FAN, TAOYUAN CITY (TW)

(21) Appl. No.: 19/074,604

(22) Filed: Mar. 10, 2025

(30) Foreign Application Priority Data
Oct. 24, 2024 (TW) 113140640

(51) Int. Cl. G01R 31/28; G01R 1/073; G01R 35/00

(52) U.S. Cl. CPC G01R 31/2891; G01R 1/07342; G01R 31/2893; G01R 35/005

(57) ABSTRACT

A single wafer level circuit testing system includes: a carrier stage provided with an object placement area; an axis control platform provided below the carrier stage; a height adjustment member configured to provide a component placement member with a variable height over a range of movement of the axis control platform; an upper optical sensor provided on the height adjustment component; a lower optical sensor configured to move under the control of the axis control platform and capture images from bottom to top; and a suction module provided on the component placement member, wherein the suction module is configured to suction an object to be tested, and wherein the object to be tested contacts a probe card from top to bottom when the component placement member drives the suction module to move downward.

### CROSS REFERENCE TO RELATED APPLICATIONS

The present invention claims priority of the Taiwan Patent Application No. 113140640, filed on Oct. 24, 2024 with the Taiwan Intellectual Property Office, which is incorporated by reference in the present invention in its entirety.

### FIELD OF INVENTION

The present application relates to a single wafer level circuit testing system and testing method thereof, and in particular, to a testing system and testing method thereof suitable for single wafer level circuits.

### BACKGROUND OF INVENTION

Currently, with the shrinkage of wafers and technological upgrades, single wafer-level circuits are widely used in electronic devices. Advanced single-wafer-level circuits often include connections between micro-optical circuits and circuits. Although this type of wafer-level circuit has better performance; correspondingly, for the manufacturer, the technical costs and manufacturing risks required to invest have also increased significantly, and the difficulty of verifying the product has also increased.

Traditional wafer testing can easily cause surface damage to the wafer, and is difficult to meet the accuracy requirements of currently single-wafer-level circuits. If currently measurement equipment is directly used to perform automated single-wafer-level circuit measurement, it will easily cause damage to the object to be tested and excessive measurement data errors. In view of this, it is necessary to provide a single wafer level circuit testing system and testing method thereof to solve the above technical problems.

### SUMMARY OF INVENTION

In order to solve the above-mentioned problems of the prior art, the purpose of the present application is to provide a single wafer-level circuit testing system and a testing method thereof, which can automatically measure wafer-level circuits quickly and accurately, and can improve measurement efficiency in response to measurement results.

In a first aspect, the present application provides a single wafer level circuit testing system, including: a carrier stage provided with an object placement area; an axis control platform provided below the carrier stage, wherein the axis control platform is configured to drive the carrier stage to move; a height adjustment member configured to provide a component placement member with a variable height above a movement range of the axis control platform; an upper optical sensor provided on the component placement member, wherein the upper optical sensor is configured to capture images from top to bottom; a lower optical sensor configured to move under the control of the axis control platform, wherein the lower optical sensor is configured to capture images from bottom to top; and a suction module provided on the component placement member, wherein the suction module is configured to suction an object to be tested, and wherein the object to be tested contacts a probe card from top to bottom when the component placement member drives the suction module to move downward.

In some embodiments of the present application, the axis control platform is also connected to an optical scale system for measuring the movement of each axis.

In some embodiments of the present application, the optical scale system further records the coordinates of the object to be tested when the object to be tested is moved below the upper optical sensor; and wherein the axis control platform is further configured to move the object to be tested below the suction module based on the coordinates of the object to be tested.

In some embodiments of the present application, the lower optical sensor is also configured to detect the object to be tested from bottom to top when the object to be tested is suctioned by the suction module.

In some embodiments of the present application, the single wafer level circuit test system further includes: a processing unit; a processing unit; wherein the suction module also includes an internal feedback element, wherein the internal feedback element outputs feedback data when the object to be tested contacts the probe card, and wherein the processing unit is configured to determine a starting point of a pressing depth based on the feedback data.

In some embodiments of the present application, the stage further includes a calibration area where a calibration mask is placed; wherein the lower optical sensor is calibrated with the upper optical sensor through the calibration mask when the calibration mask is placed in the calibration area and moved below the upper optical sensor by the axis control platform.

In some embodiments of the present application, the probe card is also moved to below the upper optical sensor through the axis control platform to be captured the image for positioning; and wherein the height adjustment member drives the object to be tested to contact the probe card based on the positioning position of the upper optical sensor.

In some embodiments of the present application, the suction module includes an air-cooling module or a refrigeration cooling module.

In a second aspect of the present application, the present application also provides a single wafer level circuit testing method, including: using a carrier stage, wherein the carrier stage is provided with an object placement area for placing an object to be tested; driving the carrier stage to move through an axis control platform; driving an upper optical sensor to capture images from top to bottom by using a height adjustment member; driving a lower optical sensor to capture images from bottom to top by using the axis control platform; suctioning the object to be tested by using a suction module; and driving the suction module to move downward by the height adjustment member, so that the object to be tested contacts a probe card from top to bottom.

Compared with the prior art, the present application provides a single wafer level circuit testing system, which uses a carrier stage to carry the object to be tested, locates a position of the object to be tested through the axis control platform and feeds back the movement parameters. The upper optical sensor and the lower optical sensor locate a coordinate system of the object to be tested and the measurement device to improve the measurement accuracy of single-wafer-level circuits. Moreover, through the height adjustment member and the suction module, the object to be tested is brought into contact with the probe card from top to bottom, while improving the measurement efficiency and avoiding damage to the contact portion between the object to be tested and the probe card, and improving a test efficiency the single wafer level circuit.

The purpose, technical solution, characteristics and achieved effects of the present application will be more easily understood through detailed descriptions of specific embodiments and accompanying figures.

### DESCRIPTION OF FIGURES

FIG. 1 discloses a three-dimensional schematic diagram of a single wafer level circuit testing system according to one embodiment of the present application.

FIG. 2 discloses a three-dimensional schematic diagram of a single wafer level circuit testing system equipped with a calibration mask according to one embodiment of the present application.

FIG. 3A discloses an initial operation state diagram of a single wafer level circuit testing system placing an object to be tested according to one embodiment of the present application.

FIG. 3B discloses a schematic diagram of an operation status of the single wafer level circuit testing system capturing an image of the object to be tested according to one embodiment of the present application.

FIG. 4A discloses a schematic diagram of the operation status of the single wafer level circuit testing system suctioning the object to be tested according to one embodiment of the present application.

FIG. 4B discloses a schematic diagram of the operation status of calibrating single-wafer-level circuit test system by using lower optical sensor according to one embodiment of the present application.

FIG. 5A discloses an operating state diagram of the positioning probe card of the single wafer level circuit testing system according to one embodiment of the present application.

FIG. 5B discloses an operating state diagram of controls the object to be tested to contact the probe card of the single wafer-level circuit test system according to one embodiment of the present application.

FIG. 6A discloses a three-dimensional schematic diagram of an air-cooling module of the single wafer-level circuit testing system according to one embodiment of the present application.

FIG. 6B discloses a partial cross-sectional view of the air-cooling module of the single wafer level circuit testing system according to one embodiment of the present application.

FIG. 7A discloses a three-dimensional schematic diagram of a refrigeration chip cooling module of the single wafer-level circuit testing system according to one embodiment of the present application.

FIG. 7B discloses a partial cross-sectional view of the refrigeration chip cooling module of the single wafer level circuit testing system according to one embodiment of the present application.

FIG. 8 discloses a schematic flow chart of a single wafer level circuit testing method according to one embodiment of the present application.

### DETAILED DESCRIPTION OF PREFERRED EMBODIMENTS

The technical solutions in the embodiments of the present application will be clearly and completely described below in conjunction with the accompanying figures in the embodiments of the present application. Obviously, the described embodiments are only part of the embodiments of the present application, not all embodiments. In addition, it should be understood that the specific embodiments described here are only used to illustrate and explain the present application, and are not used to limit the present application.

Please refer to the accompanying figures, where the same or similar components are represented by the same component numbers.

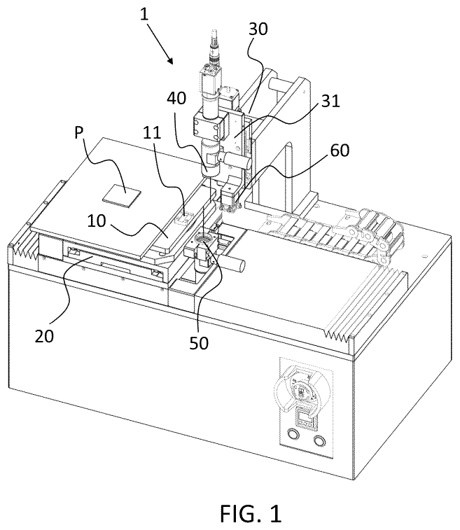

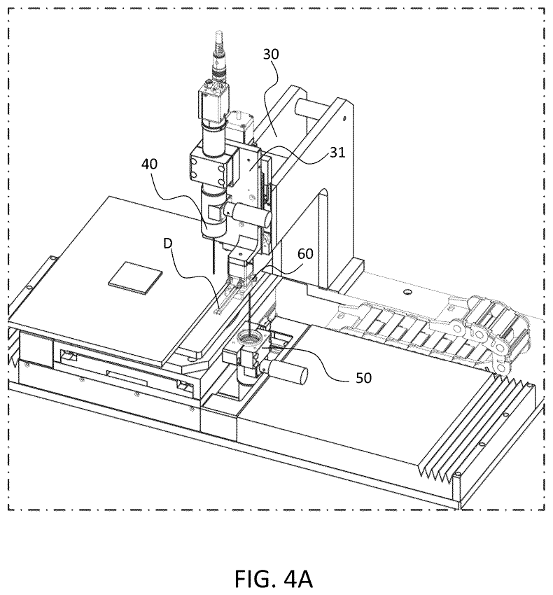

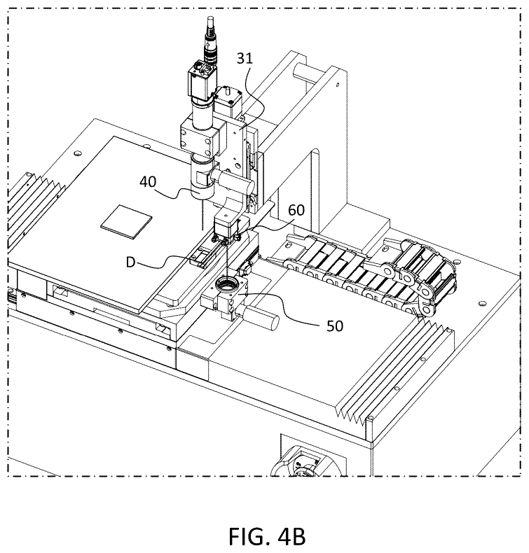

First, please refer to FIG. 1 and FIG. 4A, FIG. 1 discloses a three-dimensional schematic diagram of a single wafer level circuit test system according to one embodiment of the present application. FIG. 4A discloses a schematic diagram of the operation status of the single wafer level circuit testing system suctioning the object to be tested according to one embodiment of the present application. The single wafer level circuit testing system 1 includes: a carrier stage 10 provided with an object placement area 11; an axis control platform 20 provided below the carrier stage 10 and is configured to drive the carrier stage 10 to move; a height adjustment member 30 provided a component placement member 31 with a variable height above a movement range L of the axis control platform 20; an upper optical sensor 40 provided on the component placement member 31 and configured to capture images from top to bottom; a lower optical sensor 50 configured to move under the control of the axis control platform 20, wherein the lower optical sensor 50 is configured to capture images from bottom to top; and a suction module 60 is provided on the component placement member 31 and wherein the suction module 60 is configured to suction the object to be tested D, and wherein the object to be tested D contacts a probe card P from top to bottom when the component placement member 31 drives the suction module 60 to move downward.

In one embodiment provided by the present application, the axis control platform 20 is also connected to an optical scale system for measuring the movement of each axis. Through the setting of the optical scale system, the single wafer level circuit test system 1 can precisely position and control the probe card P mounted on the carrier stage 10, as well as the movement of the upper optical sensor 40 toward the carrier stage 10 according to the movement distance measured by the optical scale system.

In one embodiment provided by the present application, the optical scale system further records the coordinates of the object to be tested D when the object to be tested D is moved below the upper optical sensor 40; and wherein the axis control platform 20 is further configured to move the object to be tested D below the suction module 60 based on the coordinates of the object to be tested D. Moreover, the axis control platform 20 is also configured to position the object to be tested D and the probe card P when the suction module 60 suctions the object D according to the feedback coordinates of the optical scale system. In one embodiment provided by the present application, when the object D is suctioned by the suction module 60, the lower optical sensor 50 is further configured to position the object D from bottom to top.

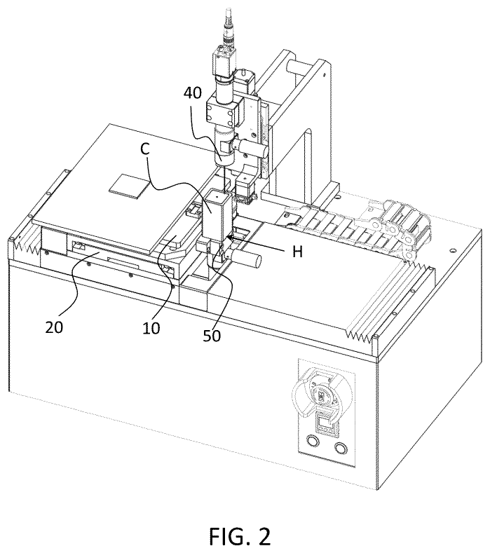

For details, please refer to the operating status of the single wafer level circuit test system disclosed in FIGS. 2 to 5B below.

Please refer to FIG. 2, FIG. 2 discloses a three-dimensional schematic diagram of a single wafer level circuit testing system equipped with a calibration mask according to one embodiment of the present application. In the embodiment provided in the present application, the carrier stage 10 also includes a calibration area H where the correction mask C is placed. The lower optical sensor 50 is calibrated with the upper optical sensor 40 through the calibration mask C when the correction mask C is placed in the calibration area H and is moved below the upper optical sensor 40 by the axis control platform 20. The calibration area H can be disposed above the lower optical sensor 50.

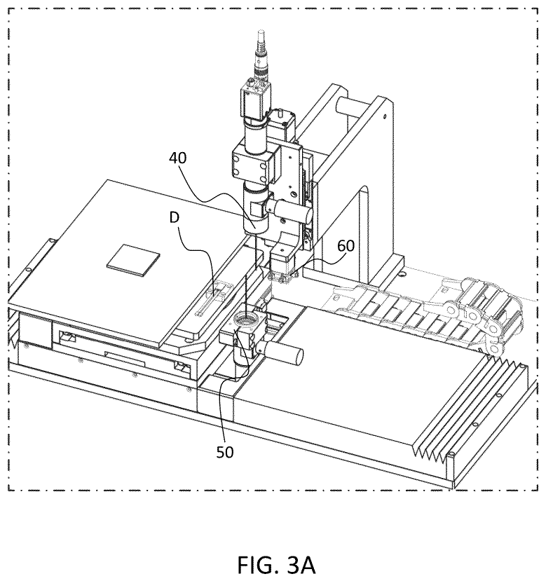

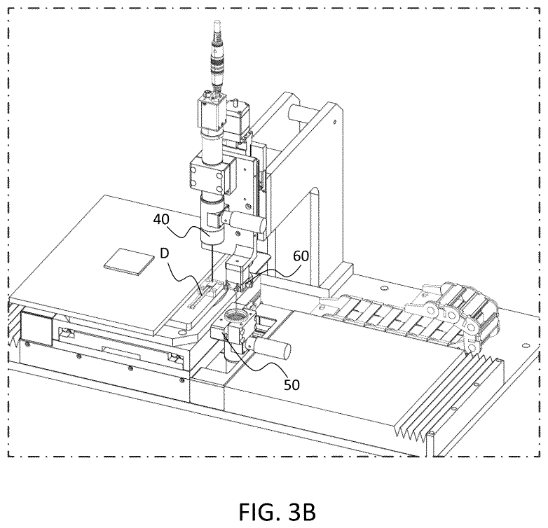

Please refer to FIGS. 3A and 3B, FIG. 3A discloses an initial operation state diagram of a single wafer level circuit testing system placing an object to be tested according to one embodiment of the present application. FIG. 3B discloses a schematic diagram of an operation status of the single wafer level circuit testing system capturing an image of the object to be tested according to one embodiment of the present application. As shown in the figure, in an initial operating state of the single wafer level circuit testing system, the object to be tested D is placed in the object placement area on the carrier stage 10, and then the height adjustment member 30 moves the component placement member 31 downward, the upper optical sensor 40 is driven down by the component placement member 31 to an imaging capturing height of the upper optical sensor 40. At this time, the upper optical sensor 40 captures an image of the object to be tested D, and the single wafer level circuit testing system 1 records the coordinates of the object to be tested D based on the image captured by the upper optical sensor 40.

Please refer to FIG. 4A and FIG. 4B in combination, wherein FIG. 4B discloses a schematic diagram of the operation status of calibrating single-wafer-level circuit test system by using lower optical sensor according to one embodiment of the present application. After the upper optical sensor 40 captures an image of the object to be tested D, the axis control platform 20 moves the object to be tested D below the suction module 60, and then the height adjustment member 30 drives the component placement member 31 to move downward, through the suction module 60 suction the object to be tested D. The axis control platform 20 drives the lower optical sensor 50 and moves the lower optical sensor 50 to below the object to be tested D when the object to be tested D is sucked by the suction module 60, and take the image through the lower optical sensor 50. At this time, the single wafer level circuit testing system 1 obtains the coordinate system including the object to be tested D and the suction module 60 based on the imaging content of the lower optical sensor 50.

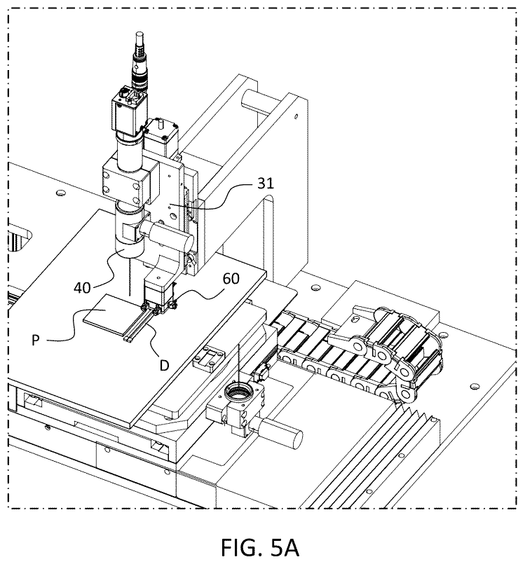

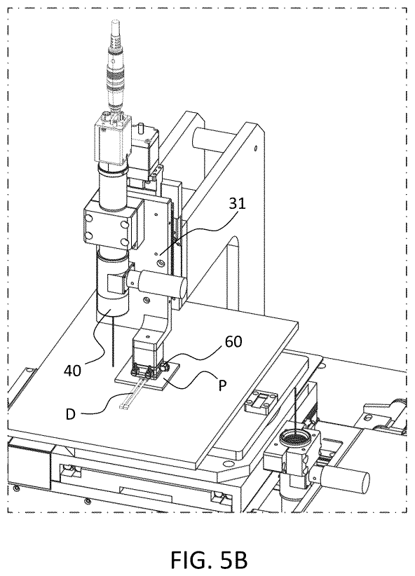

Please refer to FIGS. 5A and 5B, wherein FIG. 5A discloses an operating state diagram of the positioning probe card of the single wafer level circuit testing system according to one embodiment of the present application, FIG. 5B discloses an operating state diagram of controls the object to be tested to contact the probe card of the single wafer-level circuit test system according to one embodiment of the present application. In one embodiment provided by the present application, the single wafer level circuit test system also includes: a processing unit; the suction module 60 also includes an internal feedback component, wherein the suction module 60 also includes an internal feedback element, wherein the internal feedback element outputs feedback data when the object to be tested D contacts the probe card P, and wherein the processing unit is configured to determine a starting point of a pressing depth based on the feedback data. When the suction module 60 suctions the object to be tested D, the axis control platform 20 moves the probe card P below the upper optical sensor 40, and captures and positions the probe card P through the upper optical sensor 40. The height adjustment member 30 drives the object to be tested D to contact the probe card P based on the positioning position of the upper optical sensor 40. That is, the height adjustment member 30 drives the component placement member 31 to a standby position. Then, the axis control platform 20 drives the suction module 60 to align the object to be tested D and the probe card P according to the obtained coordinate system. After the axis control platform 20 aligns the object to be tested D and the probe card P, the height adjustment member 30 drives the component placement member 31 to descend, so that the object to be tested D touches the probe card P.

In one embodiment provided by the present application, the internal feedback component inside the suction module 60 is a load cell. The load cell provides feedback to the single wafer-level circuit testing system 1, indicating whether the object to be tested D is in contact with the probe card P.

In one embodiment provided by the present application, when the single wafer level circuit testing system 1 receives feedback data for the first time, it sets this depth as the starting point of the pressing depth. Subsequently, based on the data returned by the weighing sensor (loadcell), the single wafer level circuit testing system 1 controls the component placement member 31 to drive the object to be tested D on the suction module 60 to press downward to a specific depth.

In one embodiment provided by the present application, the suction module 60 includes an air-cooling module or a refrigeration cooling module.

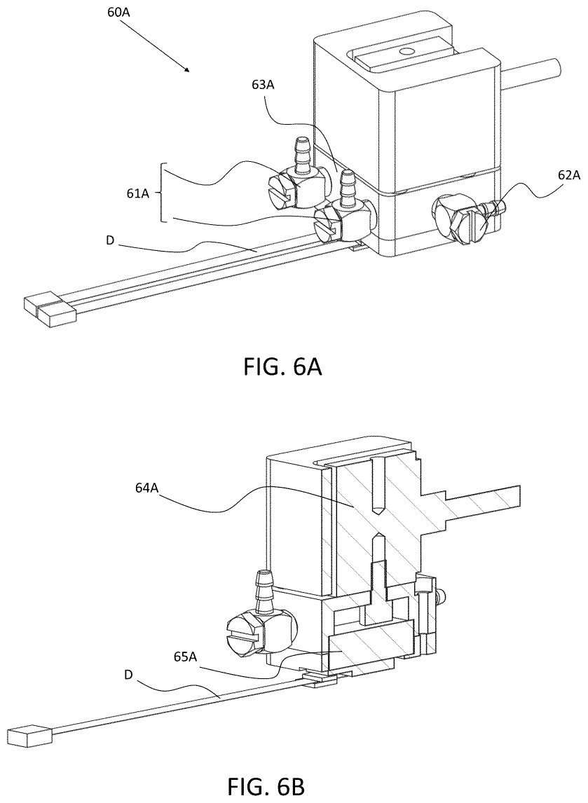

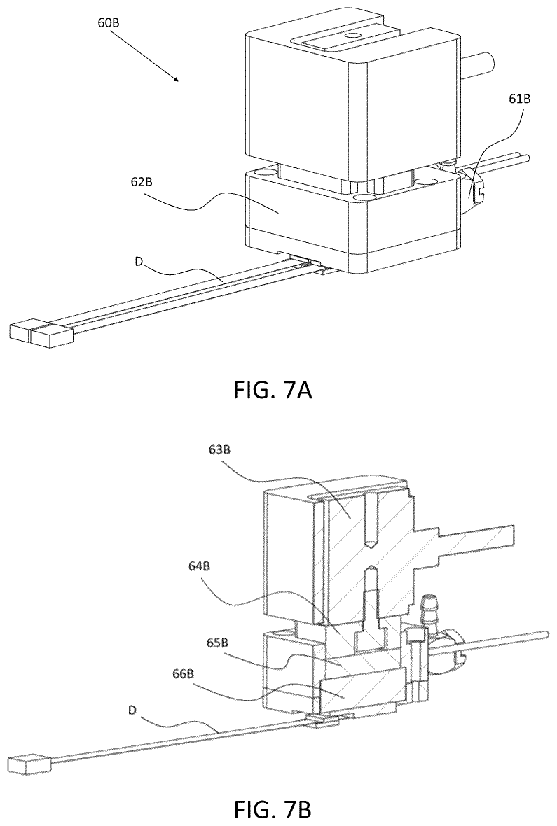

Please refer to an internal structure of the suction module 60 shown in FIGS. 6A to 7B below.

Please refer to FIGS. 6A and 6B. FIG. 6A discloses a three-dimensional schematic diagram of an air-cooling module of the single wafer-level circuit testing system according to one embodiment of the present application. FIG. 6B discloses a partial cross-sectional view of the air-cooling module of the single wafer level circuit testing system according to one embodiment of the present application. In this embodiment, the suction module 60 includes an air-cooling module 60A, which consists of an air-cooling circuit 61A, a vacuum circuit 62A, and a heat dissipation element 63A. A weighing sensor 64A is integrated into the air-cooling module 60A, with a silicon carbide porous ceramic 65A positioned beneath the weighing sensor 64A, wherein the weighing sensor 64A can be a loadcell. The air-cooling circuit 61A cools the heat dissipation element to regulate the temperature of the silicon carbide porous ceramic 65A. Consequently, when the suction module 60 holds the object to be tested D, the air-cooling module 60A also cools the object D, enhancing test accuracy.

Please refer to FIGS. 7A and 7B. FIG. 7A discloses a three-dimensional schematic diagram of a refrigeration chip cooling module of the single wafer-level circuit testing system according to one embodiment of the present application. FIG. 7B discloses a partial cross-sectional view of the refrigeration chip cooling module of the single wafer level circuit testing system according to one embodiment of the present application. In this embodiment, the suction module 60 includes a cooling wafer cooling module 60B. The refrigeration wafer cooling module 60B includes a vacuum circuit 61B and a heat dissipation element 62B. Moreover, inside the refrigeration chip cooling module 60B, a weighing sensor (loadcell) 63B is provided, with a heat insulation layer 64B positioned below the weighing sensor 63B. The refrigeration chip 65B is located below the heat insulation layer 64B, and a silicon carbide porous ceramic 66B is located below the refrigeration chip 65B. In this embodiment, the refrigeration chip cooling module 60B performs heat exchange through the refrigeration chip 65B to control the temperature of the silicon carbide porous ceramic 66B. Consequently, when the suction module 60 holds the object to be tested D, the present application can also cool the object to be tested D through the refrigeration chip cooling module 60B, thereby improving test accuracy.

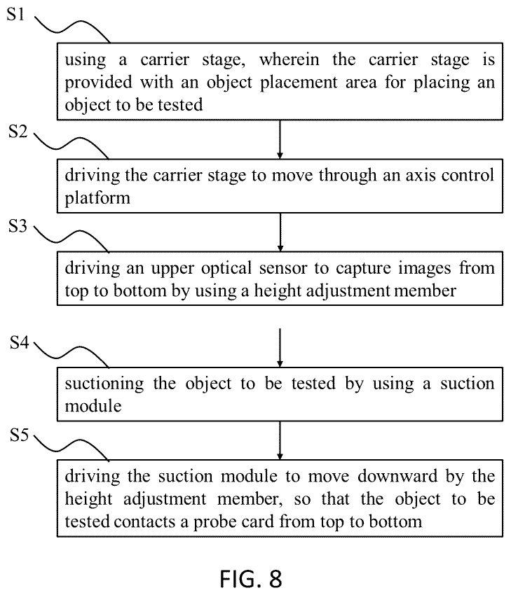

Please refer to FIG. 8, FIG. 8 discloses a schematic flow chart of a single wafer level circuit testing method according to one embodiment of the present application. The present application also provides a single wafer level circuit testing method, including:

S1: using a carrier stage, wherein the carrier stage is provided with an object placement area for placing an object to be tested.

S2: driving the carrier stage to move through an axis control platform.

By setting an object placement area for the object to be tested on the carrier stage, when the carrier is moved, the object to be tested moves along with the carrier stage when the carrier stage is moved. Therefore, the positioning of the object to be tested can be positioned by positioning the carrier stage. When the carrier stage remains stationary, the suction module configured for top-to-bottom operation can directly pick up the object to be tested.

S3: driving an upper optical sensor to capture images from top to bottom by using a height adjustment member.

The upper optical sensor is driven by the height adjustment member. When an object to be tested is placed on the carrier stage and needs to be moved, the upper optical sensor can be raised to provide space for the object to be tested to move. The upper optical sensor is lowered to the phase-taking distance of the object to be tested through the height adjustment member only when it is time to capture an image.

S4: suctioning the object to be tested by using a suction module.

By adsorbing the object to be tested, the present application reduces surface damage of the object to be tested. Additionally, when the suction module absorbs the object to be tested, the suction module can be combined with a heat exchange circuit to cool down the object to be tested.

S5: driving the suction module to move downward by the height adjustment member, so that the object to be tested contacts a probe card from top to bottom.

By making the object to be tested contact the probe card from top to bottom, the present application reduces surface damage caused by the contact and further improves test accuracy.

Compared with prior art, the present application provides a single wafer level circuit testing system that uses a carrier stage to carry the object to be tested. The single wafer level circuit testing system locates the object to be tested through an axis control platform and feeds back movement parameters. The upper optical sensor and the lower optical sensor determine the coordinate system of both the object to be tested and the measurement device, improving the measurement accuracy of single wafer level circuits. Additionally, by using the height adjustment member and suction module, the object to be tested is brought into contact with the probe card from top to bottom, improving measurement efficiency, preventing damage at the contact point, and enhancing testing efficiency. Moreover, by adsorbing the object to be tested with the suction module, the surface integrity of the object to be tested is preserved, while the internal feedback component precisely controls the contact degree between the object to be tested and the probe card, maintaining the migration rate of the object to be tested and improving measurement accuracy.

It should be noted that the combination of various elements in the present application preferably forms the above-mentioned multiple embodiments, but this should not be interpreted as a limitation of the present application. That is, there can be more combinations of various elements in the present application, not limited to the above-mentioned embodiments.

This article uses specific examples to illustrate the principles and implementation methods of the present application. The description of the above embodiments is only used to help understand the technical solution of the present application. Those of ordinary skill in the art should understand that they can still modify the technical solutions recorded in the foregoing embodiments, or make equivalent substitutions for some of the technical features. However, these modifications or substitutions do not cause an essence of the corresponding technical solutions to depart from a scope of the technical solutions of the embodiments of the present application.

What is claimed is:

1. A single wafer level circuit testing system, comprising:
a carrier stage provided with an object placement area;
an axis control platform provided below the carrier stage, wherein the axis control platform is configured to drive the carrier stage to move;
a height adjustment member provided a component placement member with a variable height above a movement range of the axis control platform;
an upper optical sensor provided on the component placement member, wherein the upper optical sensor is configured to capture images from top to bottom;
a lower optical sensor configured to move under the control of the axis control platform, wherein the lower optical sensor is configured to capture images from bottom to top; and
a suction module provided on the component placement member, wherein the suction module is configured to suction an object to be tested, and wherein the object to be tested contacts a probe card from top to bottom when the component placement member drives the suction module to move downward.

2. The single wafer level circuit testing system according to claim 1, wherein the axis control platform is also connected to an optical scale system for measuring the movement of each axis.

3. The single wafer level circuit testing system according to claim 2, wherein the optical scale system further records the coordinates of the object to be tested when the object to be tested is moved below the upper optical sensor; and
wherein the axis control platform is further configured to move the object to be tested below the suction module based on the coordinates of the object to be tested.

4. The single wafer level circuit testing system according to claim 1, wherein the lower optical sensor is also configured to detect the object to be tested from bottom to top when the object to be tested is suctioned by the suction module.

5. The single wafer level circuit test system according to claim 1, which further comprising:
a processing unit;
wherein the suction module also comprises an internal feedback element, wherein the internal feedback element outputs feedback data when the object to be tested contacts the probe card, and wherein the processing unit is configured to determine a starting point of a pressing depth based on the feedback data.

6. The single wafer level circuit testing system according to claim 1, wherein the stage further comprises a calibration area where a calibration mask is placed;
wherein the lower optical sensor is calibrated with the upper optical sensor through the calibration mask when the calibration mask is placed in the calibration area and moved below the upper optical sensor by the axis control platform.

7. The single wafer level circuit testing system according to claim 1, wherein the probe card is also moved to below the upper optical sensor through the axis control platform to be captured the image for positioning; and
wherein the height adjustment member drives the object to be tested to contact the probe card based on the positioning position of the upper optical sensor.

8. The single wafer level circuit testing system according to claim 1, wherein the suction module comprises an air-cooling module or a refrigeration cooling module.

9. A single wafer level circuit testing method, comprising:
using a carrier stage, wherein the carrier stage is provided with an object placement area for placing an object to be tested;
driving the carrier stage to move through an axis control platform;
driving an upper optical sensor to capture images from top to bottom by using a height adjustment member;
driving a lower optical sensor to capture images from bottom to top by using the axis control platform;
suctioning the object to be tested by using a suction module; and
driving the suction module to move downward by the height adjustment member, so that the object to be tested contacts a probe card from top to bottom.

10. The single wafer level circuit testing method according to claim 9, wherein the lower optical sensor is further configured to position the object to be tested from bottom to up when the object to be tested is suctioned by the suction module.
